(19) United States
(12) Patent Application Publication
(10) Pub. No.: US 2005/0238816 A1
(43) Pub. Date: Oct. 27, 2005

(54) Method and apparatus of depositing low temperature inorganic films on plastic substrates

(76) Inventors: Li Hou, Cupertino, CA (US); Tae Kyung Won, San Jose, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 10/831,407

(22) Filed: Apr. 23, 2004

(51) Int. Cl. H05H 1/24

(52) U.S. Cl. 427/569; 118/723 R

(57) ABSTRACT

A method and apparatus for depositing a low temperature inorganic film onto large area plastic substrates are described in this invention. Low temperature (<80° C.) inorganic films do not adhere very well to the plastic substrate. Therefore, a low temperature (<80° C.) plasma pre-treatment is added to improve the adhesion property. The inorganic film with plasma pre-treatment shows good adhesion and hermetic properties.

### BACKGROUND OF THE INVENTION

1. Field of the Invention

Embodiments of the present invention generally relate to the deposition of thin films using chemical vapor deposition processing. More particularly, this invention relates to a method and apparatus of depositing low temperature inorganic films onto large area plastic substrates.

2. Description of the Related Art

Organic light emitting diode (OLED) displays have gained significant interest recently in display applications in view of their faster response times, larger viewing angles, higher contrast, lighter weight, lower power and amenability to flexible substrates, as compared to liquid crystal displays (LCD). Organic light-emitting diode (OLED) display becomes a serious contender for LCD display after efficient electroluminescence (EL) from a bilayer organic light-emitting device was reported by C. W. Tang and S. A. Van Slyke in 1987. A large number of organic materials are known to have extremely high fluorescence quantum efficiencies in the visible spectrum, including the blue region, with some approaching 100%. In this regard, organic materials are ideally suited for multicolor display applications. However, the development of organic EL devices had not been successful due to the high voltage required to inject charges into single layer organic crystals. The discovery by C. W Tang and S. A Van Slyke of a double layers or organic materials, in contrast to the single layer of organic materials sandwiched between two injecting electrodes, with one layer capable of only monopolar (hole) transport and the other for electroluminescence, lowers the operating voltage and makes practical application of OLED possible.

Following discovery of the bi-layer OLED, the organic layers in OLED have evolved into multiple layers with each layer serving a different function. The OLED cell structure consists of a stack of organic layers sandwiched between a transparent anode and a metallic cathode. FIG. 1 shows an example of an OLED device structure that is build on a substrate 101. After a transparent anode layer 102 is deposited on the substrate 101, a stack of organic layers are deposited on the anode layer 102. The organic layers could comprise a hole-injection layer 103, a hole-transport layer 104, an emissive layer 105, an electron-transport layer 106 and an electron injection layer 107. It should be noted that not all 5 layers of organic layers are needed to build an OLED cell. The bi-layer OLED device, described in page 913, volume 51 of Applied Physics Letter in 1987, contains only a hole-transport layer 104 and an emissive layer 105. Following the organic layer deposition, a metallic cathode 108 is deposited on top of the stack of organic layers. When an appropriate voltage 110 (typically a few volts) is applied to the cell, the injected positive and negative charges recombine in the emissive layer to produce light 120 (electroluminescence). The structure of the organic layers and the choice of anode and cathode are designed to maximize the recombination process in the emissive layer, thus maximizing the light output from the OLED devices.

Early investigation indicated that OLEDs have a limited lifetime, characterized by a decrease in EL efficiency and an increase in drive voltage. A main reason for the degradation of OLEDs is the formation of non-emissive dark spots due to moisture or oxygen ingress. The emissive layer is often produced from 8-hydroxyquinoline aluminum (Alq₃) (see FIG. 2 for chemical structure). Exposure to humid atmospheres is found to induce the formation of Alq₃ crystalline structures in an initially amorphous film. The formation of crystalline clusters in the Alq3 layers causes cathode delamination, and hence, creates non-emissive dark spots which grow in time.

Thus, there is still a need for methods of depositing passivation films onto large area plastic substrate with good hermetic and adhesion properties to protect the OLED devices underneath.

### SUMMARY OF THE INVENTION

Embodiments of a method and apparatus of depositing a low temperature inorganic film onto a substrate are provided. In one embodiment, a low temperature thin film deposition method for depositing an inorganic film onto a substrate comprises placing the substrate in a deposition process chamber, performing a plasma treatment process on the substrate, and depositing an inorganic film at a temperature less than 80° C. on the substrate.

In another embodiment, a method of depositing a low temperature inorganic film onto a substrate comprises placing the substrate in a deposition process chamber, performing a plasma treatment process on the substrate, and depositing an inorganic film at a temperature less than 80° C. on the substrate with a gas mixture of a silicon-containing gas and either a nitrogen-containing gas (or gases), or an oxygen-containing gas.

In another embodiment, an apparatus to deposit an inorganic film at a temperature less than 80° C. onto a substrate comprises a deposition process chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) depicts a cross-sectional schematic view of an OLED device.

FIG. 2 (Prior Art) shows the chemical structure of 8-hydroxyquinoline aluminum (Alq₃).

FIG. 3 depicts a cross-sectional schematic view of a basic OLED device with a hermetic layer deposited on top.

FIG. 4 shows the chemical structure of diamine.

FIG. 5 shows the process flow of depositing a thin film on a substrate in a process chamber.

FIG. 6 is a schematic cross-sectional view of an illustrative processing chamber having one embodiment of a gas distribution plate assembly of the present invention.

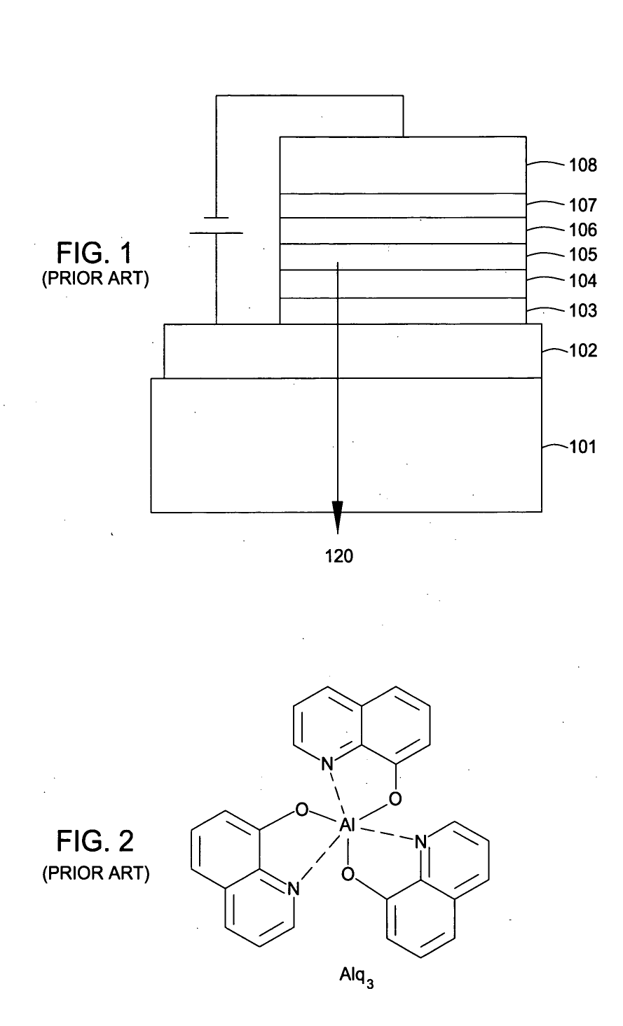

### DETAILED DESCRIPTION OF THE PREFERRED EMBODIMENT

The present invention generally relates to a method and apparatus of depositing low temperature films onto large area plastic substrates. The invention applies to any devices, such as OLED, organic TFT, solar cell, etc., on plastic substrates. The substrate could be circular for semiconductor wafer manufacturing or polygonal, such as rectangular, for flat panel display manufacturing. The surface area rectangular substrate for flat panel display is typically large, for example a rectangle of at least about 300 mm by about 400 mm (or 120,000 mm²).

The invention is illustratively described below in reference to a plasma enhanced chemical vapor deposition system configured to process large area substrates, such as a plasma enhanced chemical vapor deposition (PECVD) system, available from AKT, a division of Applied Materials, Inc., Santa Clara, Calif. However, it should be understood that the invention has utility in other system configurations such as other chemical vapor deposition systems and any other film deposition systems, including those systems configured to process round substrates.

Plasma enhanced chemical vapor deposition (PECVD) films, such as silicon nitride (SiN), silicon oxynitride (SiON) and silicon oxide (SiO), were developed in the early seventies as an effective passivation overcoat for metallization on the planar portions of silicon integrated circuit (IC) chips. Since then, SiN, SiON and SiO films have also been applied in electronic packaging for plastic encapsulated microcircuits as effective barrier layers against moisture, air and corrosive ions. SiN and SiON films are especially effective in blocking against moisture and air and have good hermetic property. Depositing a passivation layer with hermetic property on top of the OLEDs greatly reduces the existing problem with non-emissive dark spots and lengthens the lifetime of the devices. It is important to be noted that the presence of residual moisture in the organic layers may also promote the Alq₃ crystallization process even in encapsulated devices.

Due to concerns over thermal stability of the organic layers, the passivation layer deposition process should be kept at low temperature, such as below 80° C. In addition to good hermetic property, the passivation film also needs to adhere well to the plastic substrate to ensure the film does not detach from the substrate surface and let moisture and air penetrate to degrade the devices underneath that the film is supposed to passivate.

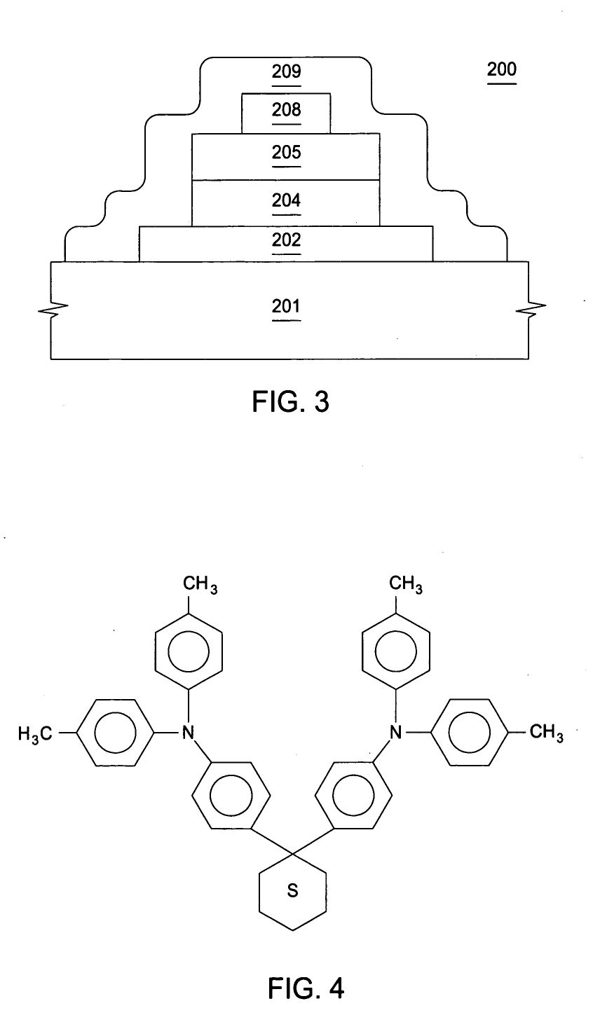

FIG. 3 shows an example of a basic OLED device structure. A transparent anode layer 202 is deposited on a substrate 201, which could be made of glass or plastic, such as polyethyleneterephthalate (PET) or polyethylenenapthalate (PEN). An example of the transparent anode layer 202 is an indium-tin-oxide (ITO) with the thickness in the range of 200 Å to 2000 Å. A hole-transport layer 204 is deposited on top of the anode layer 202. Examples of the hole-transport layer 204 include: diamine (see FIG. 4 for chemical structure), which is a naphthyl-substituted benzidine (NPB) derivative, and N,N′-diphenyl-N,N′-bis(3-methylphenyl)-(1,1′-biphenyl)-4,4′-damine (TPD), in the range of 200 Å to 1000 Å. TPD can be deposited on a substrate by thermal evaporation from a baffled Mo crucible in a vacuum chamber with a base pressure less than 2×10⁶ Torr.

Following the hole-transport layer 204 deposition, an emissive layer 205 is deposited. Materials for the emissive layer 205 typically belong to a class of fluorescent metal chelate complexes. An example is 8-hydroxyquinoline aluminum (Alq₃). The thickness of the emissive layer is typically in the range of 200 Å to 1500 Å. Following the emissive layer 205 deposition, the organic layers are patterned. A top electrode 208 is then deposited and patterned. The top electrode 208 could be a metal, a mixture of metals or an alloy of metals. An example of the top electrode is an alloy of magnesium (Mg), silver (Ag) and aluminum (Al) in the thickness range of 1000 Å to 3000 Å.

After the OLED device construction is complete, a passivation layer 209 is deposited. Examples of a passivation layer with hermetic property include silicon nitride (SiN) or silicon oxynitride SiON, deposited in the thickness range of 300 Å to 5000 Å.

Due to concerns over thermal stability of the organic layers, the passivation layer deposition process should be kept at low temperature, such as below 80° C. SiN film can be deposited by flowing a silicon containing gas, such as SiH₄, at flow rate between about 100 sccm to about 500 sccm, a nitrogen-containing gas, such as NH₃, between about 100 sccm to about 500 sccm, and/or another nitrogen-containing gas, such as N₂, between about 2000 sccm to about 6000 sccm, under RF power between about 400 watts to about 2000 watts, pressure between about 0.5 Torr to about 5.0 Torr, between gas diffuser plate and substrate surface between about 0.4 inch to about 1.1 inch, and deposition temperature between about 40° C. to about 80° C. SiON film can be deposited by flowing a silicon-containing gas, such as SiH₄, at flow rate between about 50 sccm to about 500 sccm, an oxygen-containing gas, such as N₂O, between about 200 sccm to about 2000 sccm, and a nitrogen-containing gas, such as N₂, between about 3000 sccm to about 6000 sccm, under RF power between about 400 watts to about 2000 watts, pressure between about 0.5 Torr to about 5.0 Torr, spacing between gas diffuser plate and substrate surface between about 0.4 inch to about 1.4 inch, and deposition temperature between about 40° C. to about 80° C. SiO film can be deposited by flowing a silicon-containing gas, such as SiH₄, at flow rate between about 100 sccm to about 600 sccm, an oxygen-containing gas, such as N₂O, between about 5000 sccm to about 15000 sccm, under RF power between about 1000 watts to about 4000 watts, pressure between about 0.5 Torr to about 5.0 Torr, spacing between gas diffuser plate and substrate surface between about 0.4 inch to about 1.1 inch, and deposition temperature between about 40° C. to about 80° C.

One issue for the low temperature hermetic film deposition is its adhesion property to the plastic substrate, such as PET or PEN. Without good adhesion between the passivation film and the substrate, the deposited passivation film can detach from the substrate and lose its hermeticity. A plasma treatment prior to the passivation film deposition could improve the adhesion property. The plasma treatment process also needs to be low temperature (<80° C.) due also to the concern of thermal instability of organic films underneath. The quality of adhesion is test by visual inspection and by scotch tape peeling test on deposited substrates that had been immersed in a pressure cooker with boiling water (at about 110-120° C.) for 99 minutes, which is used to stress the film integrity and adhesion property under severe moisture condition. The pressure cooker is a Farberware pressure cooker, made by Salton Incorporated of Lake Forest, Ill. Visual inspection is used to detect gross adhesion problem. If the adhesion property is “poor”, the deposited film can peel off from the substrate, can form bubbles on the substrate surface, or can appear foggy, instead of being transparent and shiny, on parts of substrate or across the entire substrate. Scotch tape peeling test is performed after the deposited substrate passes the visual inspection. The scotch tape peeling test is performed by placing the sticky side of a piece of scotch tape on the substrate surface and then pull the tape off the substrate surface. If the adhesion property is “good”, the scotch tape would come off without bringing the deposited film. If the adhesion property is not good enough, the deposited film will detach from the substrate surface and come off with the scotch tape. When the deposited passes the visual inspection but fails the scotch tape peeling test, the adhesion property is described as “fair”.

Table 1 shows the deposition conditions of various passivation films that are deposited on PET plastic substrates without plasma treatment. All films show poor adhesion to the PET substrate after being placed in the boiling water for 2 hours by visual inspection. “Poor” adhesion means you can visually see the film peeling from the substrate or the film appear “foggy” due to poor adhesion before or after pressure cooker stress. A dielectric film adheres well to the substrate should appear transparent and shiny on the substrate and make the substrate reflective. All films in Table 1 are deposited at 60° C. with thickness about 10000 Å.

TABLE 1
Deposition conditions for various passivation films that
show poor adhesion to PET without plasma treatment.

| | | | | | | Pres- | Spac- |
|---|---|---|---|---|---|---|---|
| | SiH₄ | NH₃ | N₂O | N₂ | RF | sure | ing |
| Film | (Sccm) | (sccm) | (sccm) | (sccm) | (watts) | (Torr) | (inch) |
| SiN | 250 | 300 | | 5500 | 900 | 2.1 | 0.9 |
| SiON-1 | 150 | | 750 | 4500 | 1150 | 1.9 | 0.7 |
| SiON-2 | 200 | | 750 | 4500 | 1150 | 1.9 | 0.7 |
| SiON-3 | 250 | | 750 | 4500 | 1150 | 1.9 | 0.7 |
| SiON-4 | 300 | | 750 | 4500 | 1150 | 1.9 | 0.7 |
| SiO-1 | 90 | | 7000 | | 1300 | 1.5 | 1 |
| SiO-2 | 330 | | 8000 | | 2000 | 2.0 | 0.7 |

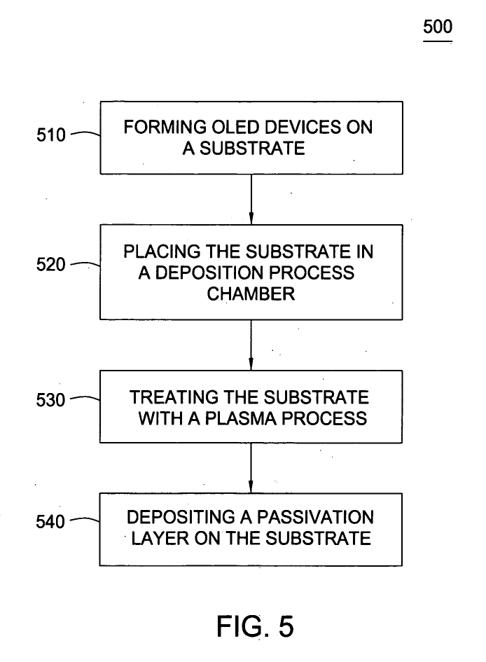

The poor adhesion results of SiN, SiON and SiO films deposited with out plasma pre-treatment in Table 1 show that a plasma pre-treatment described below is needed to improve the adhesion between the deposited film and the substrate. FIG. 5 shows the process flow 500 of passivation layer deposition and the plasma treatment process step prior to the passivation layer deposition. Step 510 describes process of forming OLED devices on a substrate. Afterwards, the substrate is placed in a deposition process chamber at step 520. Prior to depositing a passivation layer, the substrate undergoes a plasma treatment at step 530 to increase the adhesion of the passivation layer to the substrate. After the plasma treatment step 530, the substrate receives a passivation layer deposition at step 540. Examples of inert gases include argon (Ar), helium (He), neon (Ne), xenon (Xe), krypton (Kr), and combinations thereof, of which argon and helium are generally used.

Plasma treatment can be performed with an inert gas, such as argon (Ar), helium (He), neon (Ne), xenon (Xe) or krypton (Kr), a hydrogen-containing gas, such as H₂ or NH₃, a nitrogen-containing gas, such as N₂ or NH₃, or a mixture of these gases. The flow rate of the plasma treatment gas is between 500 sccm to about 4000 sccm. The pressure of the treatment process falls between 0.1 Torr to 5 Torr. The spacing between the substrate and the gas diffuser plate is between about 0.4 inch to about 1.4 inch. The plasma power is between about 400 watts to about 3000 watts. The plasma treatment time is between 2 seconds to about 10 minutes. The parameters that can affect the treatment process include: deposited film type, substrate material, treatment gas type, treatment gas flow rate, pressure, spacing between the substrate and the gas diffuser plate, the plasma power level and plasma treatment time. Plasma can be generated in-situ or ex-situ (or remote). The plasma power source could be RF power or microwave power.

Table 2 shows the effect of Ar plasma treatment time on adhesion improvement for SiN film on PET substrate. The SiN film is deposited under 250 sccm SiH₄, 300 sccm NH₃, 5500 sccm N₂, RF at 900 watts, under pressure 2.1 Torr, at gas diffuser plate to substrate surface spacing of 0.9 inch, and at 60° C. temperature to a thickness about 5000 Å. The Ar plasma pre-treatment is process under under 1500 sccm Ar, 1.2 Torr and 1 inch gas diffuser to substrate surface spacing and at 60° C.

TABLE 2
Adhesion property as a function of
plasma treatment power and time.

| RF (watts) | Treatment time (sec) | Adhesion property |
|---|---|---|
| 0 | 0 | Poor |
| 1000 | 60 | Fair |
| 1000 | 90 | Good |
| 1000 | 120 | Good |
| 1000 | 180 | Good |
| 1800 | 30 | Good |
| 1800 | 60 | Good |
| 750 | 120 | Good |
| 750 | 240 | Fair |

The data in Table 2 show that a plasma pre-treatment at 750 watts RF power for 120 seconds gives good adhesion property, while a longer pre-treatment at 240 seconds degrades the adhesion property from good to fair. “Good” adhesion means no peeling is observed across the entire substrate either by visual inspection or by scotch tape peeling test. “Fair” adhesion means the deposited substrate passes the visual inspection, but fails the scotch tape peeling test. All deposited substrates had been immersed in a pressure cooker with boiling water for 99 minutes. The results show that longer plasma treatment does not always give better adhesion property. Table 2 data also show that the process window at 1000 watts is pretty wide, since the adhesion property is good between 90 seconds to 180 seconds. While at 1800 on property is good for 30 and 60 seconds treatment.

Table 3 shows the effect of Ar plasma treatment on adhesion improvement of two SiON films, SiON-2 and SiON-4, of thickness about 5000 angstrom. Both SiON films are deposited under 750 sccm N₂O, 4500 sccm N₂, 1150 watts, 1.9 Torr chamber pressure, 1 inch spacing between gas diffuser plate and substrate surface, and at 60° C. substrate temperature. SiON-2 deposited with 200 sccm SiH4 and SiON-4 deposited with 300 sccm SiH₄. The Ar plasma pre-treatment is process under under 1500 sccm Ar, 1.2 Torr and 1 inch spacing between gas diffuser plate and substrate surface, and at 60° C. substrate temperature.

TABLE 3
Adhesion property of two types of SiON
films with Ar plasma pre-treatment.

| | | Treatment time | |
|---|---|---|---|
| Film Type | RF (watts) | (sec) | Adhesion property |
| SiON-2 | 1000 | 90 | Fair |
| SiON-4 | 1000 | 90 | Foggy SiON-2 film |
| | | | on PET |

The results in Table 3 show that Ar pre-treatment gives only fair adhesion result for SiON-2 film, which means that it fails the scotch tape peeling test, and the SiON-4 film is found to be foggy, which reflects poor adhesion with visual inspection.

In addition to the Ar plasma treatment, H₂ plasma treatment has also been tested on the SiON films. Table 4 shows the effect of H₂ plasma treatment time on adhesion improvement of three SiON films, SiON-2, SiON-3, and SiON-4, of thickness about 5000 Å. All three SiON films are deposited under 750 sccm N₂O, 4500 sccm N₂, 1150 watts, 1.9 Torr, 0.7 inch spacing between gas diffuser plate and substrate surface, and at 60° C. substrate temperature. SiON-2 is deposited with 200 sccm SiH₄, SiON-3 deposited with 250 sccm SiH₄, and SiON-4 deposited with 300 sccm SiH₄. The H₂ plasma pre-treatment is processed under 1500 sccm H₂, 1.5 Torr, 1 inch spacing between gas diffuser plate and substrate surface, and at 60° C.

TABLE 4
Adhesion property of three types of SiON
films after H₂ plasma treatment.

| | | Spacing | Treatment time | Adhesion |
|---|---|---|---|---|
| Film Type | RF (watts) | (inch) | (sec) | property |
| SiON-2 | 1500 | 1.5 | 120 | Foggy SiON—I |
| | | | | film on PET |
| SiON-3 | 1000 | 1 | 180 | Good |
| SiON-3 | 2000 | 1 | 90 | Good |
| SiON-4 | 1500 | 1 | 120 | Good |

The H₂ plasma treatment under 1500 watts RF and 1.5 inch spacing between gas diffuser plate and substrate surface for 120 seconds results in foggy SiON-2 film on PET substrate. H₂ plasma treatment under 1000 and 2000 watts RF power, and 1 inch spacing for 90 seconds and 180 seconds results in good adhesion property between SiON-3 film and the PET substrate. SiON-4 film undergoes H₂ plasma treatment at 1500 watts RF power and 1 inch spacing for 120 seconds also show good adhesion result.

The results described above show that plasma pre-treatment with inert gas, such as Ar, or with hydrogen-containing gas, such as H₂, improve adhesion of passivation layer, such as SiN, SiON or SiO, on the plastic substrate, such as PET. The data shown here are merely to demonstrate the feasibility of using plasma treatment to improve adhesion property between inorganic passivation (or hermetic) films and plastic substrates. Deposited film type, substrate material, plasma treatment gas type, plasma treatment gas flow rates, plasma power level, plasma pressure, spacing between substrate and the gas diffuser plate and plasma treatment time can all affect the plasma treatment and affect the adhesion property.

In addition to good adhesion property, the passivation film used to protect the OLED devices also should have hermetic property. Table 5 compares the oxygen permeability of a SiON film and a SiN films. The SiN film is deposited under 250 sccm SiH₄, 300 sccm NH₃, 5500 sccm N₂, RF at 900 watts, under pressure 2.1 Torr, at gas diffuser plate to substrate surface spacing of 0.9 inch, and at 60° C. temperature to a thickness of about 5000 Å. Prior to depositing the SiN film, the PET plastic substrate goes through an Ar plasma pre-treatment. The Ar plasma pre-treatment is process under 1500 sccm Ar, 1000 watts, 1.2 Torr and 1 inch gas diffuser to substrate surface spacing and at 60° C. for 120 seconds. The deposited SiN film passes both the visual and peeling test after the deposited substrate was immersed in a pressure cooker with boiling water for 99 minutes. The SiON-5 film is deposited under 130 sccm SiH₄, 750 sccm N₂O, 4500 sccm N₂, 1150 watts, 1.9 Torr, 0.7 inch spacing between gas diffuser plate and substrate surface, and at 60° C. substrate temperature to a thickness of about 5000 Å. Prior to depositing the SiON-5 film, the PET plastic substrate goes through a H₂ plasma pre-treatment. The H₂ plasma pre-treatment is processed under 1500 sccm H₂, 1500 watts, 1.5 Torr, 1 inch spacing between gas diffuser plate and substrate surface, and at 60° C. for 120 seconds. The deposited SiON-5 film passes both the visual and peeling test after the deposited substrate was immersed in a pressure cooker with boiling water for 99 minutes. The SiON-5 film also survives an 100 hours moisture stress at 85% moisture at 85° C. (85%/85° C.). The deposition rate of SiON-5 film is about 872 Å/min with film stress at −0.50 E9 dynes/cm².

TABLE 5
O₂ permeability comparison between SiN and SiON-5 films.

| Film | O2 permeability@25° C. · day |
|---|---|
| SiN | 0.2618 c.c./m² · day |
| SiON-5 | 0.1164 c.c./m² · day |

The O₂ permeability test is performed by OX-TRAN, an oxygen permeation and transmission measuring system, made by Mocon Inc. of Minneapolis, Minn. The measurement is conducted at 25° C. on 5000 Å films deposited on PET substrates. The results show that both SiN and SiON-5 films have low oxygen permeability. The oxygen permeability of SiON-5 film is less than SiN film.

In addition to the oxygen permeability test, water permeability is also measured for SiON-5 film. The water permeability test is performed by PERMATRAN-W, a water vapor permeation and transmission rate measuring system, made by Mocon Inc. of Minneapolis, Minn. The water vapor transmission rate (WVTR) measured is 3.3 g/m².day on a 10,000 Å film deposited on a PET substrate. Aside from the collecting WVTR, extreme water permeability test is conducted by comparing the reflective index (RI) and thickness of SiON-5 film before and after immersing the deposited substrate on a Farberware pressure cooker with boiling water for 30 hours. Since it's easer to measure film thickness and RI on silicon substrate, the measurement was collected on SiON-5 film deposited on a silicon substrate. Table 6 shows the thickness and RI of SiON-5 film before and after the pressure cooker stress.

TABLE 6
Thickness and RI of SiON-5 film before and
after a 30 hours pressure cooker stress.

| | Before 30 hours | After 30 hours | % Change |
|---|---|---|---|
| | pressure cooker | pressure cooker | (After-Before)/ |
| | stress | stress | Before |
| Thickness | 10458 | 10661 | 1.94% |
| (Å) | | | |
| RI | 1.422 | 1.4146 | 0.54% |

The results show very minimal changes of thickness and reflective index (RI) after an extreme moisture stress. The results above show that the low temperature passivation films, such as SiN or SiON, deposited with a plasma pre-treatment, show good adhesion and hermetic properties.

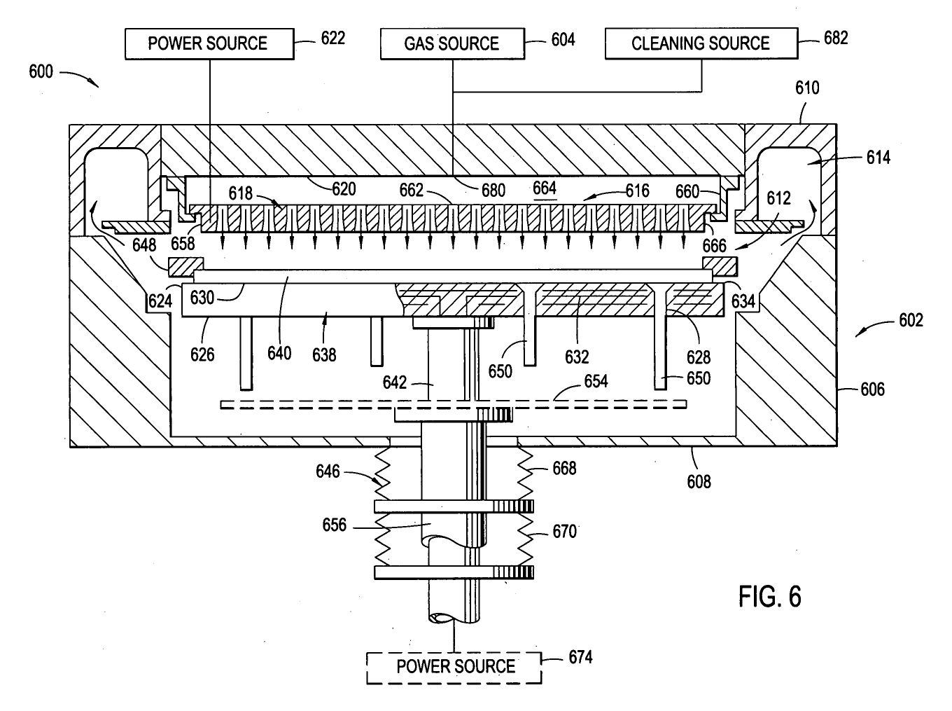

FIG. 6 is a schematic cross-sectional view of one embodiment of a plasma enhanced chemical vapor deposition system 600, available from AKT, a division of Applied Materials, Inc., Santa Clara, Calif. The system 600 generally includes a processing chamber 602 coupled to a gas source 604. The processing chamber 602 has walls 606 and a bottom 608 that partially define a process volume 612. The process volume 612 is typically accessed through a port (not shown) in the walls 606 that facilitate movement of a substrate 640 into and out of the processing chamber 602. The walls 606 and bottom 608 are typically fabricated from a unitary block of aluminum or other material compatible with processing. The walls 606 support a lid assembly 610 that contains a pumping plenum 614 that couples the process volume 612 to an exhaust port (that includes various pumping components, not shown).

A temperature controlled substrate support assembly 638 is centrally disposed within the processing chamber 602. The support assembly 638 supports the glass substrate 640 during processing. In one embodiment, the substrate support assembly 638 comprises an aluminum body 624 that encapsulates at least one embedded heater 632. The heater 632, such as a resistive element, disposed in the support assembly 638, is coupled to an optional power source 674 and controllably heats the support assembly 638 and the glass substrate 640 positioned thereon to a predetermined temperature. Typically, in a CVD process, the heater 632 maintains the glass substrate 640 at a uniform temperature between about 150 to at least about 460 degrees Celsius, depending on the deposition processing parameters for the material being deposited.

Generally, the support assembly 638 has a lower side 626 and an upper side 634. The upper side 634 supports the glass substrate 640. The lower side 626 has a stem 642 coupled thereto. The stem 642 couples the support assembly 638 to a lift system (not shown) that moves the support assembly 638 between an elevated processing position (as shown) and a lowered position that facilitates substrate transfer to and from the processing chamber 602. The stem 642 additionally provides a conduit for electrical and thermocouple leads between the support assembly 638 and other components of the system 600.

A bellows 646 is coupled between support assembly 638 (or the stem 642) and the bottom 608 of the processing chamber 602. The bellows 646 provides a vacuum seal between the chamber volume 612 and the atmosphere outside the processing chamber 602 while facilitating vertical movement of the support assembly 638.

The support assembly 638 generally is grounded such that RF power supplied by a power source 622 to a gas distribution plate assembly 618 positioned between the lid assembly 610 and substrate support assembly 638 (or other electrode positioned within or near the lid assembly of the chamber) may excite gases present in the process volume 612 between the support assembly 638 and the distribution plate assembly 618. The RF power from the power source 622 is generally selected commensurate with the size of the substrate to drive the chemical vapor deposition process.

The support assembly 638 additionally supports a circumscribing shadow frame 648. Generally, the shadow frame 648 prevents deposition at the edge of the glass substrate 640 and support assembly 638 so that the substrate does not stick to the support assembly 638. The support assembly 638 has a plurality of holes 628 disposed therethrough that accept a plurality of lift pins 650. The lift pins 650 are typically comprised of ceramic or anodized aluminum. The lift pins 650 may be actuated relative to the support assembly 638 by an optional lift plate 654 to project from the support surface 630, thereby placing the substrate in a spaced-apart relation to the support assembly 638.

The lid assembly 610 provides an upper boundary to the process volume 612. The lid assembly 610 typically can be removed or opened to service the processing chamber 602. In one embodiment, the lid assembly 610 is fabricated from aluminum (Al).

The lid assembly 610 includes a pumping plenum 614 formed therein coupled to an external pumping system (not shown). The pumping plenum 614 is utilized to channel gases and processing by-products uniformly from the process volume 612 and out of the processing chamber 602.

The lid assembly 610 typically includes an entry port 680 through which process gases provided by the gas source 604 are introduced into the processing chamber 602. The entry port 680 is also coupled to a cleaning source 682. The cleaning source 682 typically provides a cleaning agent, such as disassociated fluorine, that is introduced into the processing chamber 602 to remove deposition by-products and films from processing chamber hardware, including the gas distribution plate assembly 618.

The gas distribution plate assembly 618 is coupled to an interior side 620 of the lid assembly 610. The gas distribution plate assembly 618 is typically configured to substantially follow the profile of the glass substrate 640, for example, polygonal for large area substrates and circular for wafers. The gas distribution plate assembly 618 includes a perforated area 616 through which process and other gases supplied from the gas source 604 are delivered to the process volume 612. The perforated area 616 of the gas distribution plate assembly 618 is configured to provide uniform distribution of gases passing through the gas distribution plate assembly 618 into the processing chamber 602. Gas distribution plates that may be adapted to benefit from the invention are described in commonly assigned U.S. patent application Ser. No. 09/922,219, filed Aug. 8, 2001 by Keller et al.; Ser. No. 10/140,324, filed May 6, 2002; and Ser. No. 10/337,483, filed Jan. 7, 2003 by Blonigan et al.; U.S. Pat. No. 6,477,980, issued Nov. 12, 2002 to White et al.; and U.S. patent application Serial No. 10/417,592, filed Apr. 16, 2003 by Choi et al., which are hereby incorporated by reference in their entireties.

The gas distribution plate assembly 618 typically includes a diffuser plate 658 suspended from a hanger plate 660. The diffuser plate 658 and hanger plate 660 may alternatively comprise a single unitary member. A plurality of gas passages 662 are formed through the diffuser plate 658 to allow a predetermined distribution of gas passing through the gas distribution plate assembly 618 and into the process volume 612. The hanger plate 660 maintains the diffuser plate 658 and the interior surface 620 of the lid assembly 610 in a spaced-apart relation, thus defining a plenum 664 therebetween. The plenum 664 allows gases flowing through the lid assembly 610 to uniformly distribute across the width of the diffuser plate 658 so that gas is provided uniformly above the center perforated area 616 and flows with a uniform distribution through the gas passages 662.

The diffuser plate 658 is typically fabricated from stainless steel, aluminum (Al), anodized aluminum, nickel (Ni) or other RF conductive material. The diffuser plate 658 is configured with a thickness that maintains sufficient flatness across the aperture 666 as not to adversely affect substrate processing. In one embodiment the diffuser plate 658 has a thickness between about 1.0 inch to about 2.0 inches. The diffuser plate 658 could be circular for semiconductor wafer manufacturing or polygonal, such as rectangular, for flat panel display manufacturing. An example of a diffuser plate 658 for flat panel display application is a rectangle of about 300 mm by about 400 mm with thickness of 1.2 inch.

Although the invention has been described in accordance with certain embodiments and examples, the invention is not meant to be limited thereto. The CVD process herein can be carried out using other CVD chambers, adjusting the gas flow rates, pressure and temperature so as to obtain high quality films at practical deposition rates. The invention is meant to be limited only by the scope of the appended claims.

1. A low temperature thin film deposition method for depositing an inorganic film onto a substrate, comprising:
placing the substrate in a deposition process chamber;
performing a plasma treatment process on the substrate; and
depositing an inorganic film at a temperature less than 80 ° C. on the substrate.

2. The method of claim 1, wherein the substrate is plastic.

3. The method of claim 2, wherein the substrate is either polyethyleneterephthalate (PET) or polyethylenenapthalate (PEN).

4. The method of claim 2, wherein the thin film is a passivation film.

5. The method of claim 4, wherein the passivation film is either a silicon nitride (SiN) film, a silicon oxynitride (SiON) film, a silicon oxide (SiO) film, or a combination film thereof.

6. The method of claim 1, wherein the plasma treatment process is performed with either an inert gas, a hydrogen-containing gas, a nitrogen containing gas, or a mixture of these gases.

7. The method of claim 6, wherein the inert gas is either argon (Ar), helium (He), neon (Ne), xenon (Xe), or krypton (Kr).

8. The method of claim 6, wherein the hydrogen-containing gas is either H₂ or NH₃.

9. The method of claim 6, wherein the nitrogen-containing gas is either N₂ or NH₃.

10. The method of claim 6, wherein the gas flow rate is between about 500 sccm to about 4000 sccm, the pressure is between about 0.1 Torr to about 5 Torr, the spacing between the substrate surface and the gas diffuser plate is between about 0.4 inch to about 1.4 inch, and the power is between about 400 watts to about 3000 watts.

11. The method of claim 6, wherein the plasma treatment time is between 2 seconds to about 10 minutes.

12. The method of claim 6, wherein the plasma of the plasma treatment process is either generated in the substrate process chamber or generated remotely.

13. The method of claim 6, wherein the plasma of the plasma treatment process is either generated by RF power or by microwave power.

14. A method of depositing a low temperature inorganic film onto a substrate, comprising:
placing the substrate in a deposition process chamber;
performing a plasma treatment process on the substrate; and then depositing an inorganic film at a temperature less than 80° C. on the substrate with a gas mixture comprising a gas selected from the group consisting of a silicon-containing gas, NH3, a nitrogen-containing gas, an oxygen-containing gas, and combination thereof.

15. The method of claim 14, wherein the inorganic film is a SiN film deposited by flowing SiH4 at flow rate between about 100 sccm to about 500 sccm, NH₃ between about 100 sccm to about 500 sccm, N₂ between about 2000 sccm to about 6000 sccm, under RF power between about 400 watts to about 2000 watts, pressure between about 0.5 Torr to about 5.0 Torr, spacing between gas diffuser plate and substrate surface between about 0.4 inch to about 1.1 inch, and deposition temperature between about 40° C. to about 80° C.

16. The method of claim 14, wherein the inorganic film is a SiON film is deposited by flowing SiH₄ at flow rate between about 50 sccm to about 500 sccm, N₂O between about 200 sccm to about 2000 sccm, N₂ between about 3000 sccm to about 6000 sccm, under RF power between about 400 watts to about 2000 watts, pressure between about 0.5 Torr to about 5.0 Torr, spacing between gas diffuser plate and substrate surface between about 0.4 inch to about 1.4 inch, and deposition temperature between about 40° C. to about 80° C.

17. The method of claim 14, wherein the inorganic film is a SiO film is deposited by flowing SiH₄ at flow rate between about 100 sccm to about 600 sccm, N₂O between about 5000 sccm to about 15000 sccm, under RF power between about 1000 watts to about 4000 watts, pressure between about 0.5 Torr to about 5.0 Torr, spacing between gas diffuser plate and substrate surface between about 0.4 inch to about 1.1 inch, and deposition temperature between about 40° C. to about 80° C.

18. The method of claim 14, wherein the inorganic film has good adhesion property to the plastic substrate.

19. The method of claim 14, wherein the inorganic film is hermetic.

20. The method of claim 2, wherein the plastic substrate is a rectangle with surface area of at least 120,000 mm².

21. An apparatus to deposit an inorganic film at a temperature less than 80° C. onto a substrate, comprising:
a deposition process chamber.

22. The apparatus of claim 21, wherein the deposition process chamber is a plasma enhanced deposition process chamber.

23. The apparatus of claim 21, wherein the substrate is plastic.

24. The apparatus of claim 21, wherein the substrate is a rectangle with surface area of at least 120,000 mm².
